(19) United States
(12) Patent Application Publication
(10) Pub. No.: US 2026/0195516 A1
(43) Pub. Date: Jul. 9, 2026

(54) PHYSICAL-AWARE DE-RATING METHOD FOR ADVANCED PROCESS LAYOUT EFFECT

(71) Applicant: MEDIATEK INC., Hsinchu City (TW)

(72) Inventors: Yi-Feng Chen, Hsinchu City (TW); Yi-Chun Tsai, Hsinchu City (TW); Yuandi Surya, Hsinchu City (TW); Chin-Te Lu, Hsinchu City (TW); Shih-Yun Lin, Hsinchu City (TW); Kin Hooi Dia, Hsinchu City (TW); Tung-Kai Tsai, Hsinchu City (TW)

(73) Assignee: MEDIATEK INC., Hsinchu City (TW)

(21) Appl. No.: 19/336,471

(22) Filed: Sep. 22, 2025

Related U.S. Application Data
(60) Provisional application No. 63/741,996, filed on Jan. 6, 2025.

(51) Int. Cl. G06F 30/392; G06F 30/323

(52) U.S. Cl. CPC G06F 30/392; G06F 30/323

(57) ABSTRACT

The present invention provides a method of designing an integrated circuit, which includes the steps of: performing an APR stage translating the logical netlist into a physical layout on a silicon die; referring to an attacker cell list to determine at least one victim cell according to the physical layout; and performing an STA stage on a file corresponding to the physical layout to generate a timing report, wherein characteristics of the at least one victim cell is adjusted for the STA stage.

### CROSS REFERENCE TO RELATED APPLICATIONS

This application claims the benefit of U.S. Provisional Application No. 63/741,996, filed on January 6th, 2025. The content of the application is incorporated herein by reference.

### BACKGROUND

In modern semiconductor design, particularly at advanced process nodes, complex digital and analog circuits are constructed using a vast array of pre-designed building blocks, often referred to as cells. These cells, which may include standard cells and other cells, are strategically placed and interconnected to form a complete circuit on a silicon die. This modular approach is fundamental to achieving the high levels of integration and performance demanded by today's electronic devices.

However, a significant technical challenge exists in the current IC design methodology. Certain types of cells, especially those designed with large N+ or P+ implementation regions, can unintentionally affect the electrical characteristics of their adjacent cells. These larger N+ or P+ implementation regions are often required for specific functionalities. Despite their necessity, their presence can create a localized proximity effect or other unwanted physical interactions that are not always accurately modeled by standard design tools.

This proximity effect is particularly problematic when these large-area cells are placed adjacent to standard cells. The performance of these adjacent standard cells, which are critical for the functionality and timing of the overall circuit, can be altered. Specifically, the power consumption and timing delay of these affected cells may deviate from the nominal values that were determined during the initial simulation and calibration steps. This deviation can be substantial enough to affect the overall performance of the circuits.

Therefore, there is a continuing need in the art for an improved method and system to mitigate the adverse effects caused by certain cell types on adjacent cells, thereby ensuring that the final circuit performance aligns more closely with the predicted behavior and maintaining the integrity of the chip's design.

### SUMMARY

Therefore, one of the objectives of the present invention is to provide a circuit design that can effectively solve the problem in the prior art where the performance of cells are affected by adjacent cell(s), without significantly increasing the chip area and design burden.

In one embodiment of the present invention, a method of designing an integrated circuit comprises the steps of: performing an APR stage translating the logical netlist into a physical layout on a silicon die; referring to an attacker cell list to determine at least one victim cell according to the physical layout; and performing an STA stage on a file corresponding to the physical layout to generate a timing report, wherein characteristics of the at least one victim cell is adjusted for the STA stage.

In one embodiment of the present invention, a machine readable storage medium comprising program codes is disclosed. When the program codes are executed by a processing circuit, the processing circuit is configured to perform steps of: performing an APR stage translating the logical netlist into a physical layout on a silicon die; referring to an attacker cell list to determine at least one victim cell according to the physical layout; and performing an STA stage on a file corresponding to the physical layout to generate a timing report, wherein characteristics of the at least one victim cell is adjusted for the STA stage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart of a circuit design according to one embodiment of the present invention.

FIG. 2 shows an attacker cell and victim cells according to one embodiment of the present invention.

FIG. 3 shows a computer system configured to perform the steps shown in FIG. 1.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to …”. The terms “couple” and “couples” are intended to mean either an indirect or a direct electrical connection. Thus, if a first device couples to a second device, that connection may be through a direct electrical connection, or through an indirect electrical connection via other devices and connections.

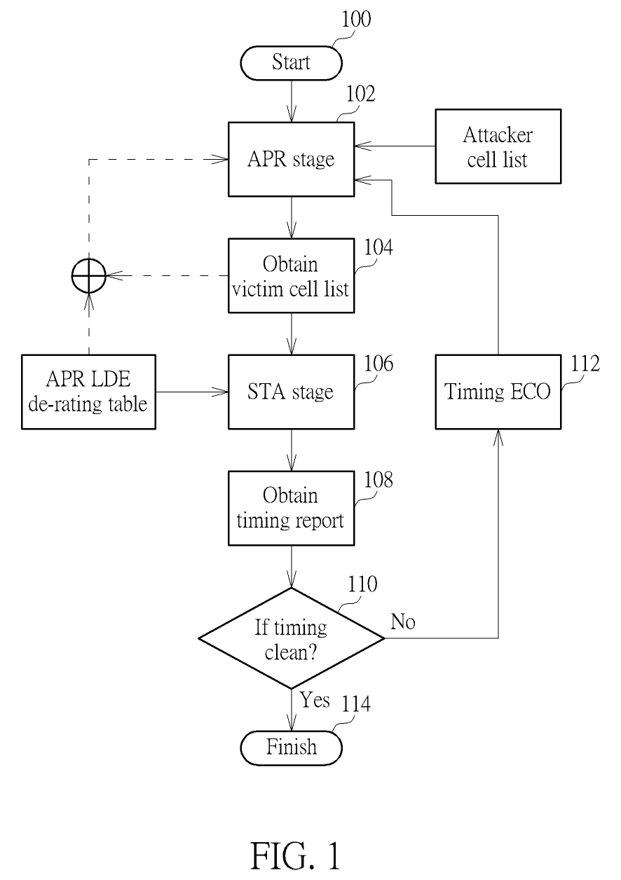

FIG. 1 is a flowchart of a method of designing integrated circuit according to one embodiment of the present invention. In Step 100, the flow starts, and the engineer has prepared a logical netlist (e.g., gate-level netlist) converted by using register-transfer level (RTL) code. In Step 102, an automatic placement and Routing (APR) stage is performed by using a processing circuit to execute corresponding program code, wherein the APR stage is responsible for translating the logical netlist into a physical layout on a silicon die. The primary objective of the APR stage is to determine the optimal physical location for each logical cell and to create the electrical interconnections between them using metal wires. The inputs to the APR stage typically include the gate-level netlist, a standard cell library, timing constraints, and technology files including the manufacturing rules. The outputs of the APR stage typically include Graphic Data System II (GDSII) file and Design Exchange Format (DEF) file. In this embodiment, in order to solve the problem in the prior art where the performance of cells are affected by adjacent cell(s), the inputs of the APR stage further comprise an attacker cell list, wherein the attacker cell list comprises at least one attacker cell which may affect the performance of the adjacent cells.

In one embodiment, the attacker cell list comprises cells having large N+ implementation regions (also known as highly doped N-type region) or large P+ implementation regions (also known as highly doped N-type region). Specifically, the attacker cell list includes attacker cells whose P+ implementation region or N+ implementation region is larger than the P+ implementation region or N+ implementation region of the standard cells. For example, the cells having large N+ implementation regions and/or the large P+ implementation regions may include level shifter, always-on-cell (i.e., circuit component that remains powered and operational even when the rest of the chip is in a low-power or sleep mode), boundary cell and/or header cell.

In Step 104, when the APR stage is executed to generate the physical layout, one or more victim cells are determined to generate a victim cell list based on the physical layout. In one embodiment, the victim cell list includes one or more cells in the physical layout that are adjacent to the attacker cell mentioned above.

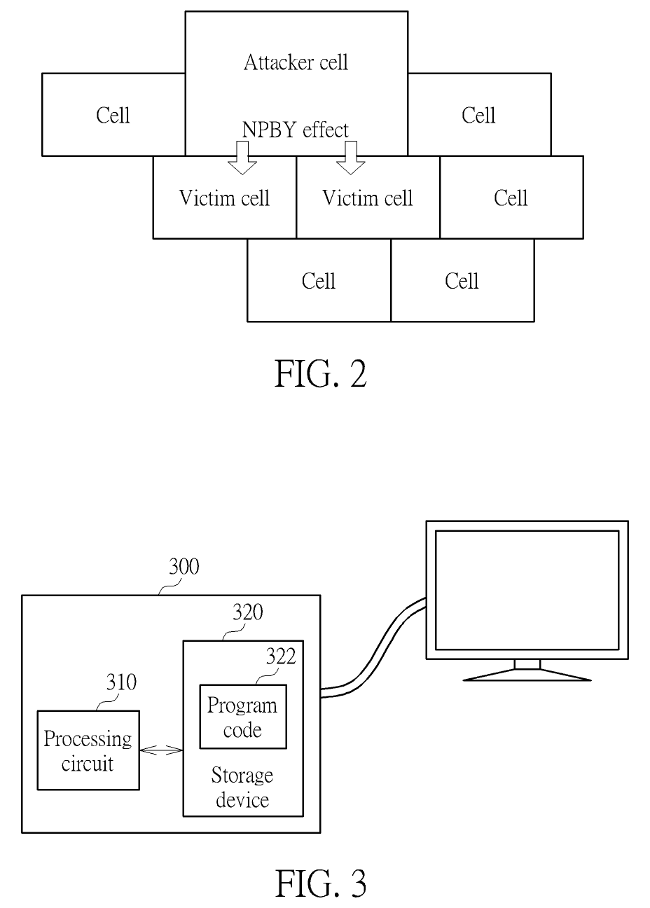

In one embodiment, referring to FIG. 2, an attacker cell can have adjacent cells in three dimensions (e.g., the mutually perpendicular x, y, and z axes). However, it has been observed that only part of these adjacent cells may be impacted. For instance, in the vertical direction (i.e., the y-direction) as shown in FIG. 2, this phenomenon is referred to as the NPBY (N+/P+ boundary at y-direction) effect. Therefore, the victim cell list can only include those cells that are adjacent to the attacker cell in the y-direction. Cells adjacent in other directions, such as the cells to the left and right of the attacker cell in FIG. 2, will not be determined as victim cells.

In one embodiment, the victim cells are standard cells, such as combinational logic cells and sequential logic cells, listed in the standard cell library.

In Step 106, after the APR stage is completed, the static timing analysis (STA) stage is performed by using a processing circuit to execute corresponding program code, based on the back-annotated netlist generated after the APR stage. In this embodiment, an APR layout dependent effect (LDE) de-rating table is used to adjust the characteristics of the victim cells in victim cell list. For example, the foundry typically provides the delay times for the standard cells, and the delay times of the victim cells may be increased for the NPBY effect. The inputs to the APR stage include back-annotated netlist, standard cell library, victim cells with adjusted characteristics, timing constraints and other files, and the APR stage is performed to find any timing violations (e.g., setup violation, hold violation) which could cause a functional failure in the final chip.

In Step 108, the STA stage outputs a timing report that lists all the timing paths and their delays, and/or lists all the timing paths and their delays

In Step 110, it is determined if the timing is clean, that is if the critical path in the physical layout has timing violation. If yes, the flow enters Step 112; and if not, the flow enters Step 114 to finish the STA stage.

In Step 112, a timing engineer change order (ECO) is performed to make small-scaled modifications to the physical layout, such as cell size adjustment, inserting buffer/inverter, rerouting wires or physical placement adjustment, to fix the timing violations mentioned in the timing report. Then, the flow goes back to Step 102.

In addition, in Step 102, the APR stage also performs some form of static timing analysis, typically a simplified or preliminary STA. This preliminary STA are mainly used for guiding routing, optimizing placement and fixing timing issues. In one embodiment, the APR stage can also refer to the APR LDE de-rating table and the victim cell list to adjust the characteristics of the victim cells in victim cell list (the victim cells have been determined during or after the APR stage), for timing optimization.

In the above-embodiment shown in FIG. 1 and FIG. 2, by providing attacker cells, determining the victim cells during the APR stage, and using the APR LDE de-rating table to adjust the characteristics of the victim cells, the timing reported generated by the STA stage can accurately reflect the actual performance of the fabricated chip during static timing analysis. In addition, because the timing ECO is performed based on the timing report generated by the STA stage using the APR LDE de-rating table to adjust the characteristics of the victim cells, and victim cells are generally located mostly on non-critical paths, this embodiment only requires modifications to a small portion of the physical layout, which avoids significantly increasing the chip area and the burden on engineers.

The flow shown in FIG. 1 can be executed by using a processing circuit to execute multiple program codes within a machine readable storage medium. Referring to FIG. 3, a computer 300 comprises at least a processing circuit 310 and a storage device 320, wherein the storage device 320 can be a hard drive, a solid-state drive or any other suitable non-volatile storage device, and the storage device stores multiple program codes 322 to executes the steps in FIG. 1. Specifically, the processing circuit 310 runs the APR software with victim cell determination functions by executing part of the program codes 322 to perform the steps 102 and 104, and the processing circuit 310 runs the STA software with victim cell characteristic adjustment mechanism by executing another part of the program codes 322 to perform the steps 106 and 108, and the processing circuit 310 further performs Steps 110 and 112 by executing yet another part of the program codes 322, wherein the files outputted by the APR stage and STA stage can be stored in the storage device 322.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of designing an integrated circuit, comprising:
performing an automatic placement and Routing (APR) stage translating the logical netlist into a physical layout on a silicon die;
referring to an attacker cell list to determine at least one victim cell according to the physical layout; and
performing an static timing analysis (STA) stage on a file corresponding to the physical layout to generate a timing report, wherein characteristics of the at least one victim cell is adjusted for the STA stage.

2. The method of claim 1, wherein the attacker cell list comprises attacker cells whose P+ implementation region is larger than the P+ implementation region of standard cells, and/or attacker cells whose N+ implementation region is larger than the N+ implementation region of the standard cells.

3. The method of claim 1, wherein the attacker cell list comprises cells corresponding to level shifter, always-on-cell, boundary cell and/or header cell.

4. The method of claim 1, wherein the attacker cell list comprises at least one attacker cell, and the step of referring to the attacker cell list to determine the at least one victim cell according to the physical layout comprises:
determining the at least one victim cell that is adjacent to the at least one attacker cell in the physical layout.

5. The method of claim 4, wherein the step of determining the at least one victim cell that is adjacent to the attacker cell in the physical layout comprises:
determining the at least one victim cell that is adjacent in a first direction to the at least one attacker cell in the physical layout;
wherein the at least one attacker cell has adjacent cells in three mutually perpendicular directions: the first direction, a second direction, and a third direction, and the adjacent cells in the second direction and the third direction are not determined as the victim cells.

6. The method of claim 4, wherein the at least one victim cell is a standard cell.

7. The method of claim 1, wherein characteristics of the at least one victim cell comprise a delay time of the at least one victim cell, and the delay time of the at least one victim cell is increased for the STA stage.

8. The method of claim 1, further comprising:
performing timing engineer change order (ECO) according to the timing report.

9. A machine readable storage medium comprising program codes, wherein when the program codes are executed by a processing circuit, the processing circuit is configured to perform steps of:
performing an automatic placement and Routing (APR) stage translating the logical netlist into a physical layout on a silicon die;
referring to an attacker cell list to determine at least one victim cell according to the physical layout; and
performing an static timing analysis (STA) stage on a file corresponding to the physical layout to generate a timing report, wherein characteristics of the at least one victim cell is adjusted for the STA stage.

10. The machine readable storage medium of claim 9, wherein the attacker cell list comprises attacker cells whose P+ implementation region is larger than the P+ implementation region of standard cells, and/or attacker cells whose N+ implementation region is larger than the N+ implementation region of the standard cells.

11. The machine readable storage medium of claim 9, wherein the attacker cell list comprises cells corresponding to level shifter, always-on-cell, boundary cell and/or header cell.

12. The machine readable storage medium of claim 9, wherein the attacker cell list comprises at least one attacker cell, and the step of referring to the attacker cell list to determine the at least one victim cell according to the physical layout comprises:
determining the at least one victim cell that is adjacent to the at least one attacker cell in the physical layout.

13. The machine readable storage medium of claim 12, wherein the step of determining the at least one victim cell that is adjacent to the attacker cell in the physical layout comprises:
determining the at least one victim cell that is adjacent in a first direction to the at least one attacker cell in the physical layout;
wherein the at least one attacker cell has adjacent cells in three mutually perpendicular directions: the first direction, a second direction, and a third direction, and the adjacent cells in the second direction and the third direction are not determined as the victim cells.

14. The machine readable storage medium of claim 12, wherein the at least one victim cell is a standard cell.

15. The machine readable storage medium of claim 9, wherein characteristics of the at least one victim cell comprise a delay time of the at least one victim cell, and the delay time of the at least one victim cell is increased for the STA stage.

16. The method of claim 9, further comprising:
performing timing engineer change order (ECO) according to the timing report.
